(19) United States
(12) Patent Application Publication
(10) Pub. No.: US 2024/0071933 A1
(43) Pub. Date: Feb. 29, 2024

(54) THREE-DIMENSIONAL PACKAGE ARCHITECTURE WITH FACE DOWN BRIDGE DIES

(71) Applicant: Intel Corporation, Santa Clara, CA (US)

(72) Inventors: Brandon C. Marin, Gilbert, AZ (US); Srinivas V. Pietambaram, Chandler, AZ (US); Gang Duan, Chandler, AZ (US); Suddhasattwa Nad, Chandler, AZ (US); Jeremy Ecton, Gilbert, AZ (US)

(73) Assignee: Intel Corporation, Santa Clara, CA (US)

(21) Appl. No.: 17/823,602

(22) Filed: Aug. 31, 2022

(51) Int. Cl. H01L 23/538; H01L 23/00; H01L 23/29; H01L 23/31; H01L 23/48; H01L 25/065

(52) U.S. Cl. CPC H01L 23/5381; H01L 23/293; H01L 23/3128; H01L 23/481; H01L 23/5386; H01L 24/08; H01L 24/16; H01L 24/81; H01L 25/0652; H01L 2224/08145; H01L 2224/16148; H01L 2224/80895; H01L 2224/80896; H01L 2224/81815; H01L 2924/182; H01L 2924/186; H01L 2924/3512; H01L 2924/37001; H01L 2924/381; H01L 2924/3841

(57) ABSTRACT

Embodiments of a microelectronic assembly comprise: a first layer comprising a plurality of first integrated circuit (IC) dies in an organic dielectric material, the first layer having a first side and a second side opposite to the first side; a second layer on the first side of the first layer, the second layer comprising a second IC die in the organic dielectric material, the second IC die conductively coupling a pair of first IC dies in the plurality of first IC dies of the first layer; and a package substrate coupled to the second side of the first layer. The second IC die is coupled to the pair of first IC dies by interconnects having a pitch less than 60 micrometers between adjacent interconnects, and the pair of first IC dies comprises TSVs conductively coupling circuits in the first IC dies with the interconnects.

### TECHNICAL FIELD

The present disclosure relates to techniques, methods, and apparatus directed to three-dimensional package architecture with face down bridge dies.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional views of an example microelectronic assembly according to some embodiments of the present disclosure.

FIG. 2 is a schematic top view of the microelectronic assembly of FIG. 1.

FIG. 3 is a schematic cross-sectional view of a portion of an example microelectronic assembly according to some embodiments of the present disclosure.

FIG. 4 is a schematic cross-sectional view of a portion of another example microelectronic assembly according to some embodiments of the present disclosure.

FIG. 5 is a schematic cross-sectional view of another example microelectronic assembly according to some embodiments of the present disclosure.

FIGS. 6A-6F are schematic cross-sectional views showing various stages of manufacture of an example microelectronic assembly according to some embodiments of the present disclosure.

FIGS. 7A-7F are schematic cross-sectional views showing various stages of manufacture of another example microelectronic assembly according to some embodiments of the present disclosure.

FIG. 8 is a cross-sectional view of a device package that includes one or more microelectronic assemblies in accordance with any of the embodiments disclosed herein.

FIG. 9 is a cross-sectional side view of a device assembly that includes one or more microelectronic assemblies in accordance with any of the embodiments disclosed herein.

FIG. 10 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

As Moore's law nears its natural limits, supercomputing faces inherent physical problems in moving toward zettascale systems. Zettascale computing aims to create 1000× the current level of compute today in or around the latter half of the decade, to take advantage of high demand for computational resources by both consumers and businesses, and to implement data hungry applications, such as artificial intelligence, machine learning and such. Zettascale supercomputers are targeted to have computing performance in the order of one zettaflops. One zettaflops equals one thousand exaflops, or one sextillion floating point operations per second. Despite advances in semiconductor processing and logic design that have permitted an increase in the amount of logic circuits that may be included in processors and other IC devices, signal speeds reach physics-based bottlenecks to achieve zettascale performance, for example, from the inherent limitations of the materials used for signal propagation, such as copper in a dielectric medium, heat transfer challenges from high intensity computations, and power delivery constraints to power several thousand simultaneous computations in multiple processors.

Many processors used in current supercomputers and other processing devices already have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer. Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

Consequently, the trend in the processor industry is to move toward disaggregation, using multiple known good chiplets (smaller sized IC dies) made using different manufacturing technologies and assembling them together into one microprocessor using novel bonding techniques. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, the individual dies are connected to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain universal serial bus (USB) standards, rather than for processing speed. Thus, by having different parts of the overall design separated into different dies, each one optimized in terms of design and manufacturing, the overall yield and cost of the combined die solution may be improved.

The connectivity between these dies is achievable by many ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The bridge and the 3D stacked architecture may also be combined to allow for top-packaged chips to communicate with other chips horizontally using the bridge and vertically, using Through-Mold Vias (TMVs) which are typically larger than TSVs. However, these current interconnect technologies use solder or its equivalent for connectivity, with consequent low vertical and horizontal interconnect density. Such solder-based packaging architecture also suffers from higher power consumption compared to on-die interconnects, increased cost to support assembly at fine pitches, and no room for error in manufacturing.

Further, in conventional 2.5D organic package architecture, bridge dies with lateral conductive pathways are provided in an organic interposer underneath two adjacent compute dies; in such package architecture, the bridge dies are between the compute dies and the package substrate, effectively reducing the area available for direct interconnections between the compute dies and the package substrate. To enable 3D organic package architecture that allows the compute dies to have direct coupling with the package substrate, the bridge dies in the interposer will need TSVs therethrough; however, assembling bridge dies with TSVs in the organic interposer has various challenges, for example, with aligning the TSVs with bond pads inside a recess in the organic interposer, or with soldering bridge dies inside the recess, among other disadvantages. While inorganic interposers can solve such challenges, they are more costly than organic packages. Further, simply moving the bridge dies to the “top” of the compute dies in organic packages is not without challenges either, because organic packages, by the inherent material properties of the organic materials used therein, such as shrinkage, high coefficient of thermal expansion, etc., are not amenable to enabling fine pitch interconnections between stacked layers of IC dies. In other words, using conventional manufacturing techniques, it is not possible to stack IC dies using interconnects that have pitches less than 60 micrometers between adjacent interconnects in an organic interposer.

Accordingly, embodiments described herein enable a microelectronic assembly that includes a first layer comprising a plurality of first IC dies in an organic dielectric material, the first layer having a first side and a second side opposite to the first side; a second layer on the first side of the first layer, the second layer comprising a second IC die in the organic dielectric material, the second IC die conductively coupling a pair of first IC dies in the plurality of first IC dies of the first layer; and a package substrate coupled to the second side of the first layer. The second IC die is coupled to the pair of first IC dies by interconnects having a pitch less than 60 micrometers between adjacent interconnects, and the pair of first IC dies comprises TSVs conductively coupling circuits in the first IC dies with the interconnects.

Various embodiments of microelectronic assembly disclosed herein comprise a pair of first IC dies mutually parallel and separated by a gap; a plurality of second IC dies coupled to the pair of first IC dies by first interconnects, the second IC dies extending across the gap, the second IC dies comprising conductive pathways between the first IC dies; and a package substrate coupled to the pair of first IC dies by second interconnects. The first IC dies are between the second IC die and the package substrate, the first IC dies and the second IC dies are surrounded by a first organic dielectric material, a redistribution layer (RDL) comprising a second organic dielectric material is between the first IC dies and the second interconnects, and the first interconnects have a pitch of approximately 25 micrometers to 60 micrometers between adjacent interconnects.

Various embodiments of microelectronic assembly disclosed herein comprise a pair of first IC dies mutually parallel and separated by a gap; a plurality of second IC dies coupled to the pair of first IC dies by first interconnects, the second IC dies extending across the gap, the second IC dies comprising conductive pathways between the first IC dies; and a package substrate coupled to the pair of first IC dies by second interconnects. The first IC dies are between the second IC die and the package substrate, the first IC dies and the second IC dies are surrounded by a first organic dielectric material, a RDL comprising a second organic dielectric material is between the first IC dies and the second interconnects, and the first interconnects have a pitch less than approximately 10 micrometers between adjacent interconnects.

Embodiments disclosed herein further include a method comprising: providing a panel comprising glass or ceramic; providing a first IC die comprising a substrate having a first side and an opposing second side, the first IC die further comprising a metallization stack in contact with the first side of the substrate; attaching the second side of the substrate of the first IC die to the panel; depositing an organic dielectric material around and over the first IC die; forming an interface layer over the metallization stack of the first IC die; attaching a pair of second IC dies to the first IC die, the attaching comprising forming at least one conductive pathway between the pair of second IC dies through the first IC die; depositing the organic dielectric material around the second IC dies; and forming an RDL over the second IC dies and the organic dielectric material around the second IC dies.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In many embodiments, an FET is a four-terminal device. In silicon-on-insulator, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

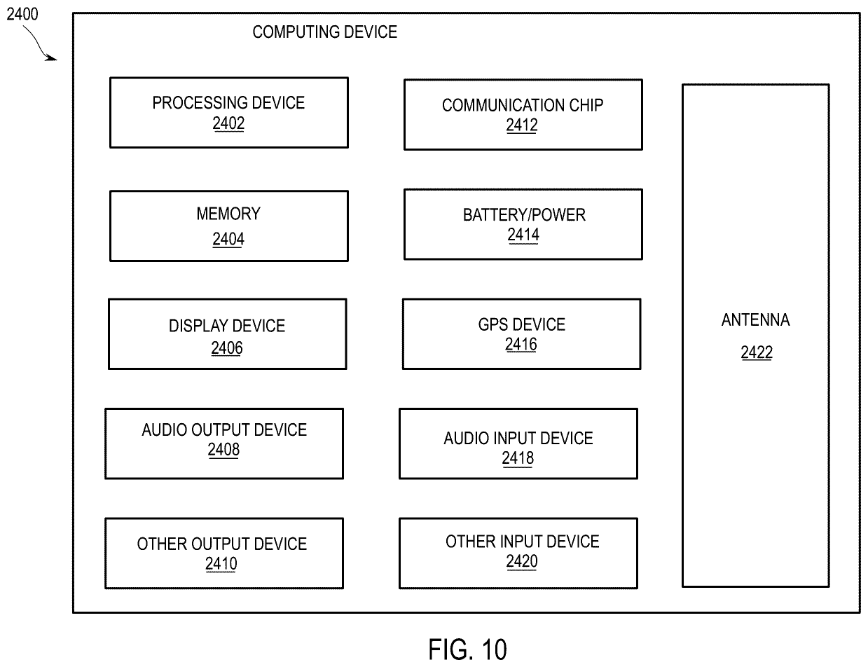

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

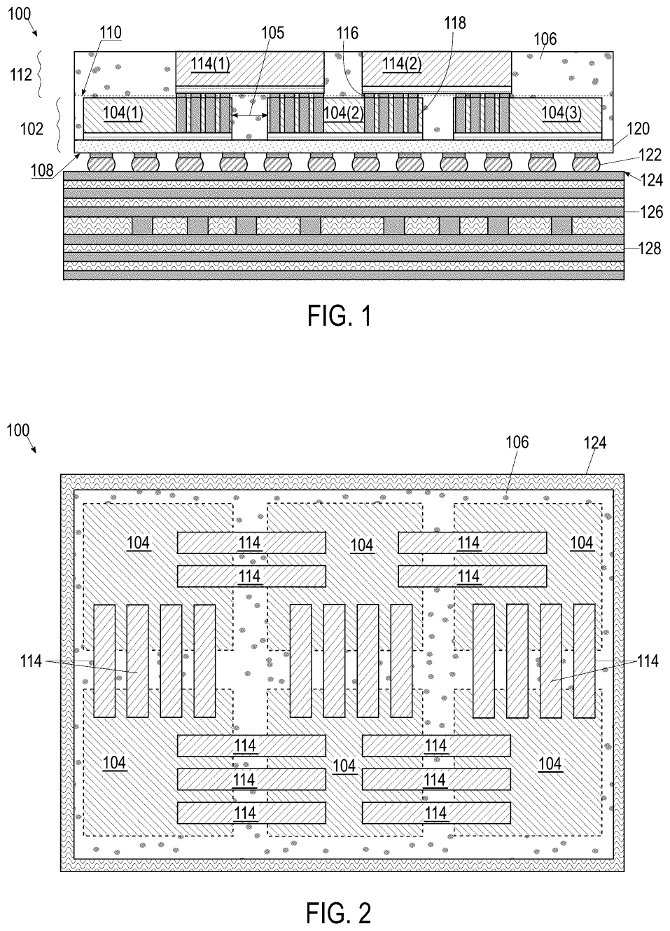

FIG. 1 is a schematic cross-sectional view of an example microelectronic assembly 100 according to some embodiments of the present disclosure. Microelectronic assembly 100 comprises a first layer 102 with a plurality of IC dies 104 in an organic dielectric material 106. In various embodiments, organic dielectric material 106 comprises epoxy. In other embodiments, organic dielectric material 106 comprises polyimide. Organic dielectric material 106 may comprise any suitable organic dielectric material typically used in package substrates as listed in the previous subsection. In various embodiments, IC dies 104 may comprise compute circuits of a microprocessor. First layer 102 has a first side 108 and a second side 110 opposite to first side 108. Microelectronic assembly 100 further comprises a second layer 112 coupled to first side 108 of first layer 102. Second layer 112 includes a plurality of IC dies 114 in organic dielectric material 106. IC dies 114 are coupled to IC dies 104 by interconnects 116. In various embodiments, interconnects 116 may have a pitch of less than approximately 60 micrometers between adjacent interconnects, depending on the type of interconnects. For example, in embodiments where interconnects 116 comprise micro-bumps with solder caps, the pitch may be in a range between approximately 25 micrometers and approximately 60 micrometers; in embodiments where interconnects 116 comprise hybrid bonds (i.e., metal-metal bonds and dielectric-dielectric bonds), the pitch may be less than 10 micrometers. In various embodiments, IC dies 114 operate as bridge dies, each of which conductively couples a pair of IC dies 104 in first layer 102. Conductive coupling of compute circuits and other circuits in IC dies 104 may be also facilitated by TSVs 118 in IC dies 104. The three-dimensional package architecture with bridge dies “over” compute dies as described herein can enable input-output scaling in organic packages without having to implement complex manufacturing constraints.

In various embodiments, second side 110 of first layer 102 may be coupled by interconnects 122 to a package substrate 124 comprising conductive traces 126 and organic dielectric material 128. In some embodiments, layers 102 and 112 may together comprise a die complex which can be handled and assembled to package substrate 124 in a manner analogous to handling and assembling an IC die, or an interposer. Examples of materials for organic dielectric material 128 are noted in the previous subsection. Note that conductive traces 126 are shown as disconnected rectangles in organic dielectric material 128, such is only for illustrative/schematic purposes and the shapes are not intended to be accurate representations of an actual package substrate. In addition, conductive vias, bond pads, redistribution layers, substrate cores, passive components, and other elements of package substrate 124 are not shown merely for ease of illustration and not as limitations. Interconnects 122 may comprise DTPS interconnects, such as flip-chip solder bonds in some embodiments, as described in the previous subsection. Interconnects 122 may have a pitch greater than the pitch of interconnects 116, for example, greater than approximately 60 micrometers between adjacent interconnects.

Whereas typical microelectronic packages with bridge dies necessarily have the bridge dies between the compute dies and the package substrate due to various manufacturing flows and architectural constraints associated therewith, embodiments of microelectronic assembly 100 provide a configuration in which IC dies 114—operating as bridge dies—are on a side of IC dies 104—operating as compute dies—opposite to package substrate 124, thereby allowing IC dies 114 to provide conductive pathways between IC dies 104 without requiring any TSVs therein, among other advantages.

FIG. 2 is a schematic top view of a portion of microelectronic assembly 100 of FIG. 1, showing the configuration of various features from a different perspective, with certain underlying features, namely. IC dies 104, shown in dotted lines for ease of explanation. First layer 102 of microelectronic assembly 100 comprises a plurality of IC dies 104, which may be arranged in an array as shown. In other embodiments, IC dies 104 may have different sizes and shapes and may be arranged in other patterns or configurations without departing from the scope of the embodiments. Second layer 112 with plurality of IC dies 114 may be arranged suitably according to the conductive coupling needs of IC dies 104. For example, a subset of IC dies 114 may couple a pair of IC dies 104. Other subsets of IC dies 114 may couple other pairs of IC dies 104 in first layer 102.

In some embodiments, at least some of IC dies 104 have a footprint area of approximately 30 millimeters by 30 millimeters. Other IC dies 104 may have a different footprint area without departing from the scope of the embodiments. In various embodiment, first layer 102 and second layer 112 together comprise a die complex having a length or a width approximately between 400 millimeters and 600 millimeters (e.g., equivalent to the size of a manufacturing panel). In some embodiments, IC dies 114 may be approximately between 60 micrometers and 80 micrometers thick, approximately between 2 millimeters and 3 millimeters in width and approximately between 4 millimeters and 8 millimeters in length. Other dimensions for IC dies 114 are also encompassed in the broad scope of the embodiments herein. A combined thickness of first layer 102 and second layer 112 is approximately between 300 micrometers and 800 micrometers in some embodiments. In other embodiments, the combined thickness may be less than 300 micrometers or more than 800 micrometers.

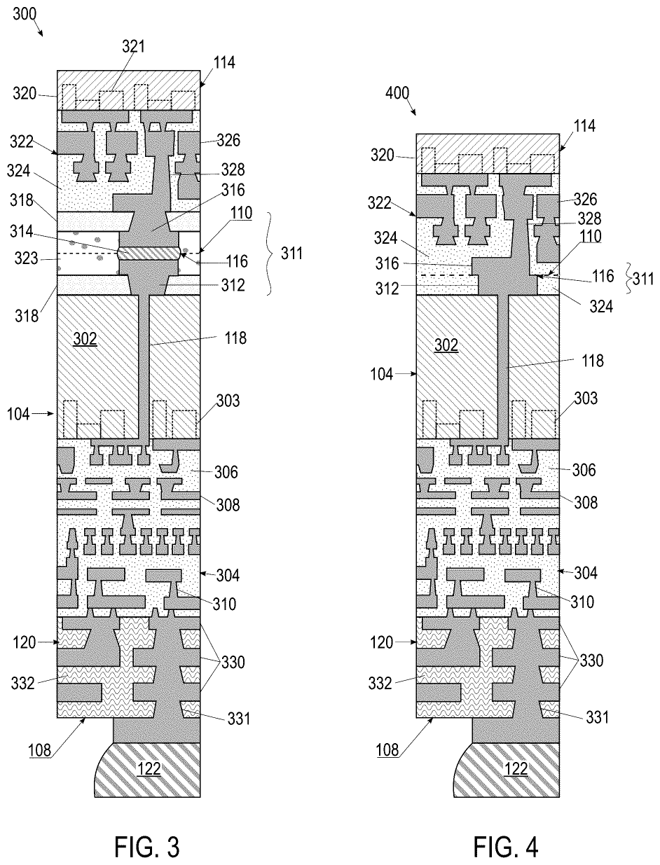

FIG. 3 is a schematic cross-sectional view of a portion 300 of an example microelectronic assembly 100 according to some embodiments of the present disclosure. Portion 300 shows a cross-sectional view of microelectronic assembly 100 between interconnect 122 and IC die 114. IC die 104 comprises a substrate 302 having active circuit elements 303 and a metallization stack 304 directly coupled to substrate 302 proximate to active circuit elements 303. Active circuit elements 303 comprise transistors, diodes, etc. as is known in the art. In various embodiments, active circuit elements 303 may comprise portions of various circuits such as compute circuits, memory circuits, etc. In various embodiments, IC die 104 may be coupled to package substrate 124 (not shown) face down, such that metallization stack 304 is proximate to side 108 of layer 102. Metallization stack 304 comprises a plurality of layers of an inorganic dielectric material 306, conductive traces 308 and conductive vias 310. In various embodiments, inorganic dielectric material 306 comprises interlayer dielectric (ILD) materials such as silicon oxide, silicon nitride, silicon carboxynitride, etc. as described in the previous subsection. Conductive traces 308 and conductive vias 310 may comprise copper. Substrate 302 may be between metallization stack 304 and an interface layer 311. Interface layer 311 comprises bond pads 312 coupled to TSVs 118 in substrate 302. Bond pads 312 of IC die 104 are coupled by solder 314 to bond pads 316 of IC die 114. Interface layer 311 also comprises solder resist 318 around bond pads 312.

IC die 114 comprises a substrate 320 having active circuit elements 321 and a metallization stack 322 directly coupled to substrate 320 proximate to active circuit elements 321. Active circuit elements 321 comprise transistors, diodes, etc. as is known in the art. In various embodiments, active circuit elements 321 may comprise portions of various circuits such as repeater circuits, timer circuits, etc. Metallization stack 322 comprises a plurality of layers of an inorganic dielectric material 324, conductive traces 326 and conductive vias 328. In various embodiments, inorganic dielectric material 324 comprises ILD materials such as silicon oxide, silicon nitride, silicon carboxynitride, etc. similar to inorganic dielectric material 306 and as described in the previous subsection. Conductive traces 326 and conductive vias 328 may comprise copper. Metallization stack 322 may be between substrate 320 and interface layer 311. Interface layer 311 may further comprise bond pads 316 coupled to conductive traces 326. Bond pads 316 may be surrounded by solder resist 318. Interface layer 311 may further comprise another organic dielectric material 323 in any gaps between layers of solder resist 318 and around interconnects 116. In some embodiments, organic dielectric material 323 may comprise an underfill material as described in the previous subsection. In various embodiments, organic dielectric material 323, for thermal purposes, may be in contact with solder resist 318 between IC dies 114 and 104.

In some embodiments as shown, interconnects 116 comprise micro-bumps including solder caps (e.g., solder 314 after reflow operations) conductively and mechanically coupled to copper pads, such as bond pads 312 and 316. In some embodiments, the micro-bumps have approximately 25 micrometers to 60 micrometers pitch between adjacent micro-bumps. Conductive pathways between active circuit elements 303 of two adjacent IC dies 104 may be through conductive traces 308, conductive vias 310, TSV 118, interconnects 116 (comprising bond pads 312, 316 and solder 314), active circuit elements 321, conductive vias 328 and conductive traces 326.

RDL 120 between IC die 104 and interconnects 122 comprises a plurality of layers of conductive traces 330 coupled by conductive vias 331 in an organic dielectric material 332. Organic dielectric material 332 is a polyimide material or another material different from organic dielectric material 106 in some embodiments. In other embodiments, organic dielectric material 332 may be of the same or similar composition as organic dielectric material 106, for example, epoxy material. In some embodiments, RDL 120 may comprise up to 10 layers of conductive traces 330 and organic dielectric material 332.

FIG. 4 is a schematic cross-sectional view of a portion 400 of another example microelectronic assembly 100 according to some embodiments of the present disclosure. The embodiment shown is substantially similar to that of FIG. 3 except interconnects 116 comprise hybrids bonds. Interface layer 311 in such embodiments comprise inorganic dielectric material 324 in contact with substrate 302 of IC die 104 and metallization stack 322 of IC die 114. Bond pads 312 and 316 of IC dies 104 and 114 respectively are bonded together by metal-to-metal bonds. Dielectric material 324 is fused throughout side 110. In various embodiments, the pitch of interconnects 116 is less than 10 micrometers between adjacent metal-to-metal bonds.

FIG. 5 is a schematic cross-sectional view of another example microelectronic assembly 100 according to some embodiments of the present disclosure. The embodiment shown is substantially similar to that of FIG. 1 except a panel 502 is coupled to layer 112. In some embodiments, panel 502 is coupled to layer 112 using an adhesive (not shown). Panel 502 may comprise glass in some embodiments. In other embodiments, panel 502 comprises ceramic.

In various embodiments, any of the features discussed with reference to any of FIGS. 1-5 herein may be combined with any other features to form a package with one or more IC dies as described herein. For example, in some microelectronic assemblies, some IC dies may be coupled by interconnects having solder and other IC dies may be coupled by hybrid bonds. Some such combinations are described above, but, in various embodiments, further combinations and modifications are possible. Various different embodiments described in different figures may be combined suitably based on particular needs within the broad scope of the embodiments.

### Example Methods

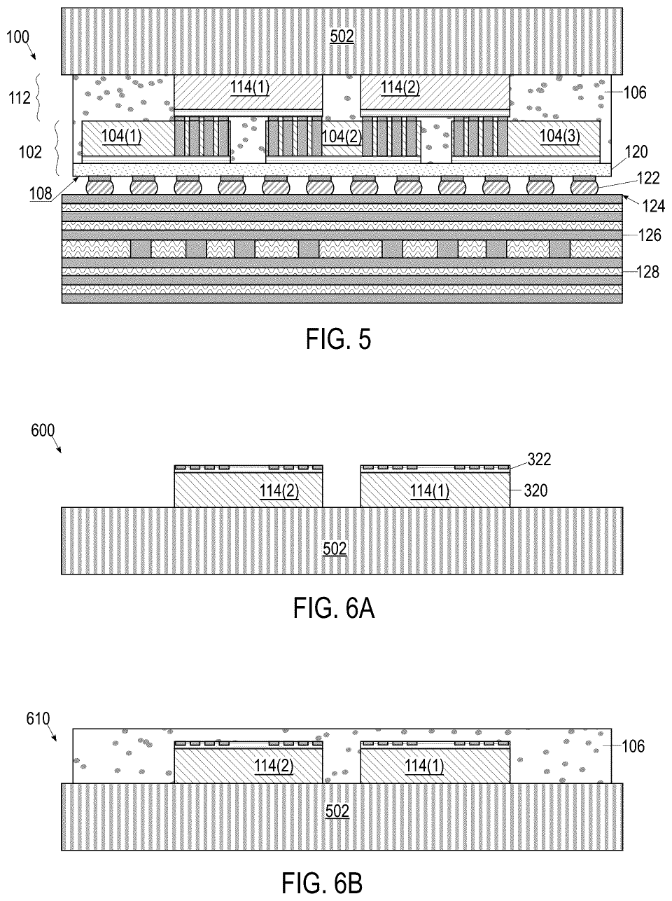

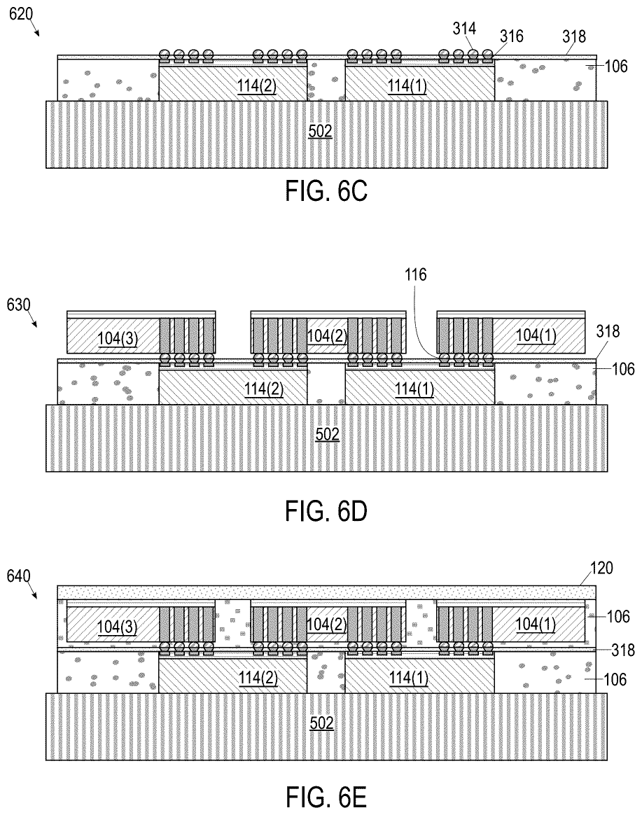

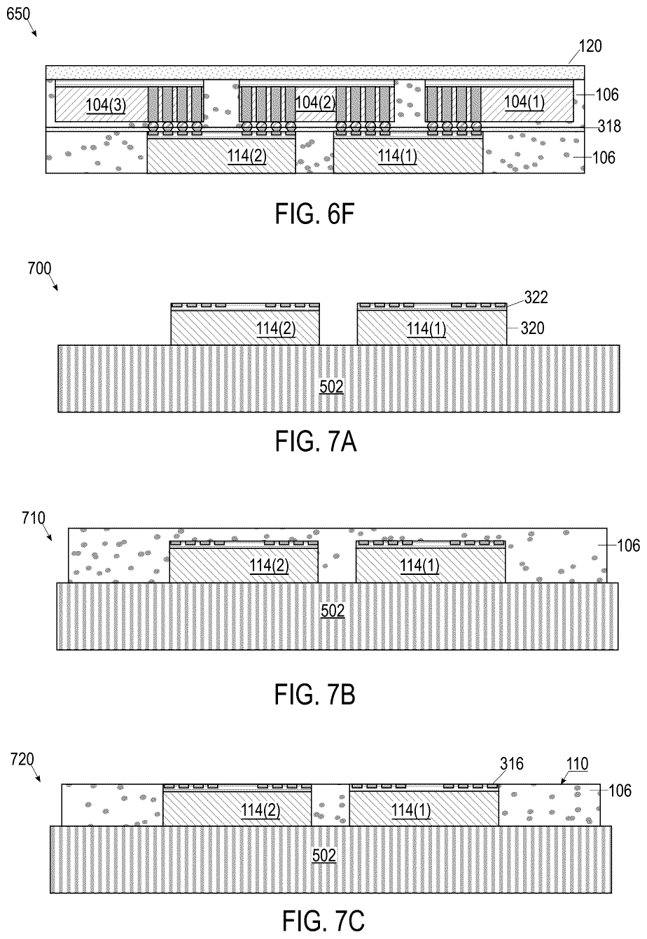

FIGS. 6A-6F are schematic cross-sectional views of various stages of manufacture of microelectronic assembly 100 according to some embodiments of the present disclosure. FIG. 6A shows an assembly 600 comprising panel 502 on which are attached a plurality of IC dies 114 (e.g., 114(1), 114(2)). In some embodiments, panel 502 is approximately between 400 millimeters by 400 millimeters to 600 millimeters by 600 millimeters in available surface area for bonding IC dies 114. IC dies 114 may be attached to panel 502 by any suitable means, including adhesive attach, soldering, etc. Respective substrates 320 of IC dies 114 are attached to panel 520, exposing respective metallization stacks 322 for further processing.

FIG. 6B shows an assembly 610 subsequent to depositing organic dielectric material 106 over panel 502 and around IC dies 114. In some embodiments, sufficient amount of organic dielectric material 106 is deposited that it covers any exposed surfaces of IC dies 114.

FIG. 6C shows an assembly 620 subsequent to forming bond pads 316 with solder 314 thereon through solder resist 318. In some embodiments, solder resist 318 may be deposited on organic dielectric material 106. Vias may be formed corresponding to bonding sites of IC dies 114. Conductive material may be electroplated to form appropriate conductive vias. Bond pads 316 may be patterned on solder resist 318. Solder 314 may be deposited on bond pads 316 appropriately. In some other embodiments, vias may be patterned in organic dielectric material 106 over bonding sites of IC dies 114. Conductive material may be electroplated to form appropriate conductive vias. Bond pads 316 may be patterned on organic dielectric material 106. Solder resist 318 may be deposited around bond pads 316. Solder 314 may be deposited on bond pads 316 and reflowed to form solder caps. Solder resist 318 along with bond pads 316 and solder 314 may comprise part of interface layer 311.

FIG. 6D shows an assembly 630 subsequent to attaching a plurality of IC dies 104 to IC dies 114, forming conductive pathways between pairs of IC dies 104 (e.g., 104(1), 104(2)) through IC dies 114 (e.g., 114(1)). In various embodiments, any one pair of IC dies 104 may be attached to a plurality of IC dies 114. In the embodiment shown, IC dies 104 are attached to IC dies 114 by a solder attachment process, such as solder reflow, and creating interconnects 116. In such embodiments, IC dies 104 may have solder resist 318 on surfaces proximate to respective bond pads 312.

FIG. 6E shows an assembly 640 subsequent to depositing additional organic dielectric material 106 around IC dies 104. In some embodiments (not shown), organic dielectric material 323 comprising underfill material may be dispensed between IC dies 104 and 114 around interconnects 116. In some embodiments, organic dielectric material 106 deposited during this operation may flow in the gaps between IC dies 104 and 114 and around interconnects 116, completing interface layer 311. RDL 120 may be created over IC dies 104 and organic dielectric material 106 around IC dies 104. In some embodiments, creating RDL 120 may comprise sequentially depositing organic dielectric material 332, forming via holes, electroplating conductive material to form conductive vias 331, patterning the electroplated conductive material to form conductive traces 330, etc. until a desired stack is obtained.

FIG. 6F shows an assembly 650 subsequent to debonding panel 502. Debonding may be achieved by laser ablation process in some embodiments where panel 502 comprises glass. In some embodiments, panel 502 may be retained, for example, for mechanical support, stability, and other considerations.

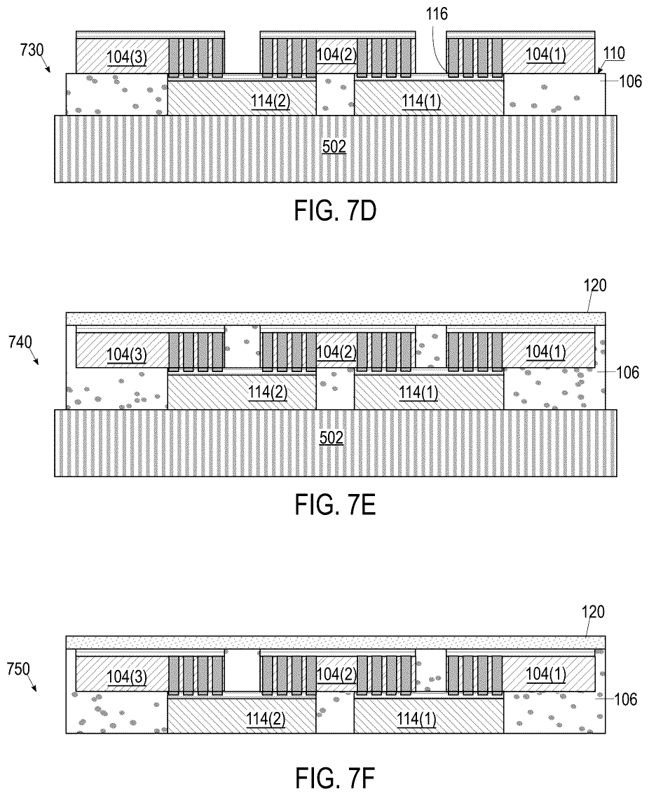

FIGS. 7A-7F are schematic cross-sectional views of various stages of manufacture of microelectronic assembly 100 according to some embodiments of the present disclosure. FIG. 7A shows an assembly 700 comprising panel 502 on which are attached a plurality of IC dies 114 (e.g., 114(1), 114(2)). In some embodiments, panel 502 is approximately between 400 millimeters by 400 millimeters to 600 millimeters by 600 millimeters in available surface area for bonding IC dies 114. IC dies 114 may be attached to panel 502 by any suitable means, including adhesive attach, soldering, etc. Respective substrates 320 of IC dies 114 are attached to panel 520, exposing respective metallization stacks 322 for further processing.

FIG. 7B shows an assembly 710 subsequent to depositing organic dielectric material 106 over panel 502 and around IC dies 114. In some embodiments, sufficient amount of organic dielectric material 106 is deposited that it covers any exposed surfaces of IC dies 114.

FIG. 7C shows an assembly 720 subsequent to planarizing side 110 and exposing bond pads 316 of IC dies 114. In various embodiments, the planarizing may be achieved by chemical mechanical polishing (CMP).

FIG. 7D shows an assembly 730 subsequent to attaching a plurality of IC dies 104 to IC dies 114, forming conductive pathways between pairs of IC dies 104 (e.g., 104(1), 104(2)) through IC dies 114 (e.g., 114(1)). In various embodiments, any one pair of IC dies 104 may be attached to a plurality of IC dies 114. In the embodiment shown, IC dies 104 are attached to IC dies 114 by hybrid bonding process, creating interconnects 116 comprising metal-to-metal bonds and inorganic dielectric to inorganic dielectric bonds.

FIG. 7E shows an assembly 740 subsequent to depositing additional organic dielectric material 106 around IC dies 104. RDL 120 may be created over IC dies 104 and organic dielectric material 106 around IC dies 104. In some embodiments, creating RDL 120 may comprise sequentially depositing organic dielectric material 332, forming via holes, electroplating conductive material to form conductive vias 331, patterning the electroplated conductive material to form conductive traces 330, etc. until a desired stack is obtained.

FIG. 7F shows an assembly 750 subsequent to debonding panel 502. Debonding may be achieved by laser ablation process in some embodiments where panel 502 comprises glass. In some embodiments, panel 502 may be retained, for example, for mechanical support, stability, and other considerations.

Although FIGS. 6-7 illustrates various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 6-7 may be modified in accordance with the present disclosure to fabricate others of microelectronic assembly 100 disclosed herein. Although various operations are illustrated in FIGS. 6-7 once each, the operations may be repeated as often as desired. For example, one or more operations may be performed in parallel to manufacture and test multiple microelectronic assemblies substantially simultaneously. In another example, the operations may be performed in a different order to reflect the structure of a particular microelectronic assembly in which one or more substrates or other components as described herein may be included.

Furthermore, the operations illustrated in FIGS. 6-7 may be combined or may include more details than described. For example, the operations may be modified suitably without departing from the scope of the disclosure for IC dies that do not have a semiconductor substrate, but rather, are fabricated on other materials, such as glass or ceramic materials. Still further, the various operations shown and described may further include other manufacturing operations related to fabrication of other components of the microelectronic assemblies described herein, or any devices that may include the microelectronic assemblies as described herein. For example, the operations not shown in FIGS. 6-7 may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

### Example Devices and Components

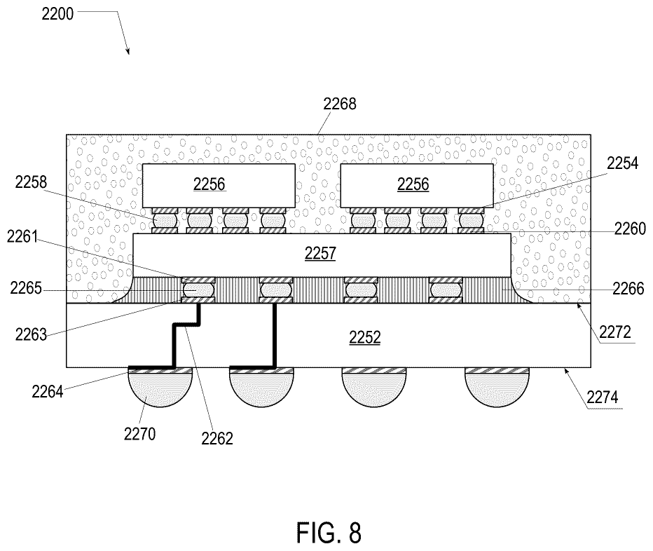

The packages disclosed herein, e.g., any of the embodiments shown in FIGS. 1-7 or any further embodiments described herein, may be included in any suitable electronic component. FIGS. 8-10 illustrate various examples of packages, assemblies, and devices that may be used with or include any of the IC packages as disclosed herein.

FIG. 8 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

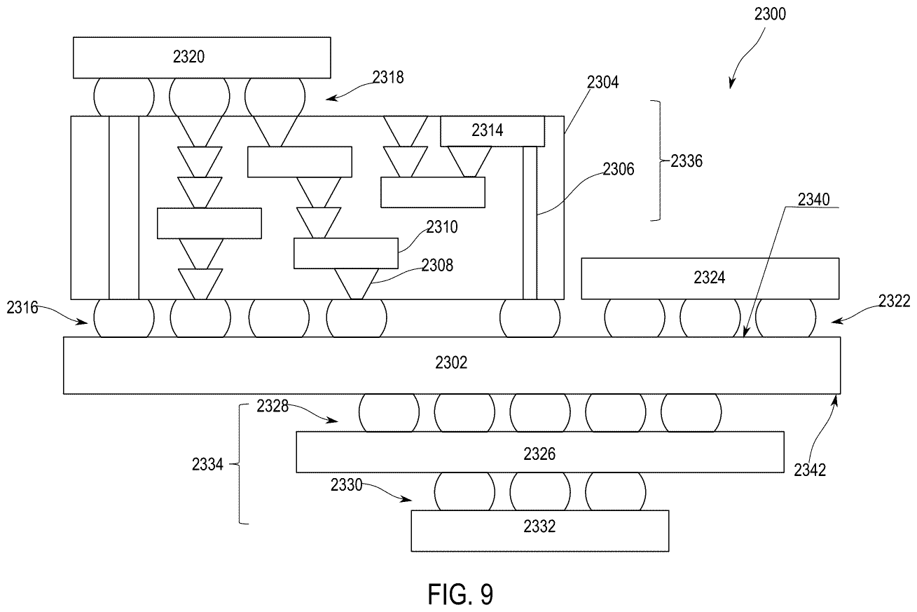

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 9.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 9 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 15. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 10 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 8). In yet another example, any one or more of the components of computing device 2400 may include an IC device assembly 2300 (e.g., as shown in FIG. 9).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single system-on-chip (SOC) die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-M RAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly (e.g., 100, FIG. 1), comprising: a first layer (e.g., 102) comprising a plurality of first IC dies (e.g., 104) in an organic dielectric material (e.g., 106), the first layer having a first side (e.g., 108) and a second side (e.g., 110) opposite to the first side; a second layer (e.g., 112) on the first side of the first layer, the second layer comprising a second IC die (e.g., 114) in the organic dielectric material, the second IC die conductively coupling a pair of first IC dies in the plurality of first IC dies of the first layer; and a package substrate (e.g., 124) coupled to the second side of the first layer, in which: the second IC die is coupled to the pair of first IC dies by interconnects (e.g., 116) having a pitch less than 60 micrometers between adjacent interconnects, and the pair of first IC dies comprises through-substrate vias (TSVs) (e.g., 118) conductively coupling circuits in the first IC dies with the interconnects.

Example 2 provides the microelectronic assembly of example 1, in which the organic dielectric material is an epoxy material.

Example 3 provides the microelectronic assembly of any one of examples 1-2, in which the second IC die does not comprise any TSVs.

Example 4 provides the microelectronic assembly of any one of examples 1-3, in which (e.g., FIG. 3, 4): the organic dielectric material is a first organic dielectric material, the first layer further comprises a redistribution layer (RDL) (e.g., 120) between the plurality of first IC dies and the second side, and the RDL comprises a plurality of layers of conductive traces (e.g., 330) and a second organic dielectric material (e.g., 332).

Example 5 provides the microelectronic assembly of example 4, in which the second organic dielectric material is a polyimide material.

Example 6 provides the microelectronic assembly of any one of examples 1-5, in which (e.g., FIG. 3, 4) active circuit elements (e.g., 303) in respective substrates (e.g., 302) of the first IC dies are proximate to the second side of the first layer, and the active regions comprise at least one of transistors and diodes (e.g., 303).

Example 7 provides the microelectronic assembly of any one of examples 1-6, in which (e.g., FIG. 3, 4) active circuit elements (e.g., 321) in a substrate (e.g., 320) of the second IC die are proximate to the first side of the first layer.

Example 8 provides the microelectronic assembly of any one of examples 1-7, in which (e.g., FIG. 2): the second layer comprises a plurality of second IC dies, a subset of the plurality of second IC dies couples the pair of first IC dies, and other subsets of the plurality of second IC dies couple other pairs of first IC dies in the first layer.

Example 9 provides the microelectronic assembly of any one of examples 1-8, in which at least some of the plurality of first IC dies have a footprint area of approximately 30 millimeters by 30 millimeters.

Example 10 provides the microelectronic assembly of any one of examples 1-9, in which the first layer and the second layer together comprise a die complex having a length or a width approximately between 400 millimeters and 600 millimeters.

Example 11 provides the microelectronic assembly of any one of examples 1-10, in which the second IC die is approximately between 60 micrometers and 80 micrometers thick, approximately between 2 millimeters and 3 millimeters in width and approximately between 4 millimeters and 8 millimeters in length.

Example 12 provides the microelectronic assembly of any one of examples 1-11, in which a combined thickness of the first layer and the second layer is approximately between 300 micrometers and 800 micrometers.

Example 13 provides the microelectronic assembly of any one of examples 1-12, in which (e.g., FIG. 3) the interconnects comprise micro-bumps including solder caps conductively and mechanically coupled to copper pads.

Example 14 provides the microelectronic assembly of example 13, in which the micro-bumps have approximately 25 micrometers to 60 micrometers pitch between adjacent micro-bumps.

Example 15 provides the microelectronic assembly of any one of examples 13-14, in which: the second layer further comprises solder resist proximate to the first side of the first layer, and an underfill material is in contact with the solder resist.

Example 16 provides the microelectronic assembly of any one of examples 1-15, in which (e.g., FIG. 4) the interconnects comprise hybrid bonds including metal-to-metal bonds and inorganic dielectric to inorganic dielectric bonds.

Example 17 provides the microelectronic assembly of example 16, in which the metal-to-metal bonds have less than approximately 10 micrometers pitch between adjacent metal to metal bonds.

Example 18 provides the microelectronic assembly of any one of examples 16-17, in which the metal comprises copper.

Example 19 provides the microelectronic assembly of any one of examples 16-18, in which the inorganic dielectric is a compound of silicon and at least one of oxygen, nitrogen, and carbon.

Example 20 provides the microelectronic assembly of any one of examples 16-19, in which: the second layer further comprises the inorganic dielectric material proximate to the first side of the first layer, and the first layer further comprises the inorganic dielectric material on the first side of the first layer.

Example 21 provides the microelectronic assembly of any one of examples 1-20, further comprising (e.g., FIG. 5): a panel (e.g., 502) comprising glass coupled to the second layer on a side of the second layer opposite to the first layer.

Example 22 provides a microelectronic assembly, comprising (e.g., FIG. 3): a pair of first IC dies (e.g., 104) mutually parallel and separated by a gap (e.g., 105); a plurality of second IC dies (e.g., 114) coupled to the pair of first IC dies by first interconnects (e.g., 116), the second IC dies extending across the gap, the second IC dies comprising conductive pathways between the first IC dies; and a package substrate (e.g., 124) coupled to the pair of first IC dies by second interconnects (e.g., 122), in which: the first IC dies are between the second IC die and the package substrate, the first IC dies and the second IC dies are surrounded by a first organic dielectric material (e.g., 106), a RDL (e.g., 120) comprising a second organic dielectric material (e.g., 332) is between the first IC dies and the second interconnects, and the first interconnects have a pitch of approximately 25 micrometers to 60 micrometers between adjacent interconnects.

Example 23 provides the microelectronic assembly of example 22, in which: the first organic dielectric material comprises epoxy, and the second organic dielectric material comprises polyimide.

Example 24 provides the microelectronic assembly of any one of examples 22-23, further comprising a glass panel coupled to the plurality of second IC dies, in which the second IC dies are between the glass panel and the first IC dies.

Example 25 provides the microelectronic assembly of any one of examples 22-24, in which the first interconnects comprise bond pads (e.g., 312, 316) coupled by solder.

Example 26 provides the microelectronic assembly of example 25, further comprising solder resist and the first organic dielectric material around each of the first interconnects.

Example 27 provides the microelectronic assembly of any one of examples 22-26, in which the RDL comprises a plurality of layers of the second organic dielectric material (e.g., 332), conductive traces (e.g., 330) and conductive vias (e.g., 331).

Example 28 provides the microelectronic assembly of example 27, in which the RDL comprises 10 layers of the second organic dielectric material.

Example 29 provides the microelectronic assembly of any one of examples 22-28, in which each of the first IC dies comprises: an interface layer comprising solder resist (e.g., 318), the first organic dielectric material, and conductive bond pads (e.g., 312); a substrate (e.g., 302) having at least one TSV (e.g., 118); and a metallization stack (e.g., 304) in contact with the substrate, the metallization stack comprising a plurality of layers of another inorganic dielectric material (e.g., 306), conductive traces (e.g., 308), and conductive vias (e.g., 310), in which: the metallization stack is between the RDL and the substrate, the substrate is between the metallization stack and the interface layer, and the first interconnects comprise the conductive bond pads of the interface layer.

Example 30 provides the microelectronic assembly of example 29, in which the TSV conductively couples the conductive traces in the metallization stack with one of the conductive bond pads of the interface layer.

Example 31 provides the microelectronic assembly of any one of examples 29-30, in which the substrate further comprises active elements (e.g., 303) proximate to the metallization stack.

Example 32 provides the microelectronic assembly of any one of examples 22-31, in which each of the second IC dies comprises: a substrate (e.g., 320); a metallization stack (e.g., 322) in contact with the substrate, the metallization stack comprising a plurality of layers of an inorganic dielectric material (e.g., 324), conductive traces (e.g., 326), conductive vias (e.g., 328), and conductive bond pads (e.g., 316); and an interface layer comprising solder resist (e.g., 318), the first organic dielectric material, and conductive bond pads (e.g., 316); in which: the metallization stack is between the interface layer and the substrate, and the first interconnects comprise the conductive bond pads of the interface layer.

Example 33 provides the microelectronic assembly of example 32, in which the substrate further comprises active elements (e.g., 321) proximate to the metallization stack.

Example 34 provides a microelectronic assembly, comprising (e.g., FIG. 4): a pair of first IC dies (e.g., 104) mutually parallel and separated by a gap (e.g., 105); a plurality of second IC dies (e.g., 114) coupled to the pair of first IC dies by first interconnects (e.g., 116), the second IC dies extending across the gap, the second IC dies comprising conductive pathways between the first IC dies; and a package substrate (e.g., 124) coupled to the pair of first IC dies by second interconnects (e.g., 122), in which: the first IC dies are between the second IC die and the package substrate, the first IC dies and the second IC dies are surrounded by a first organic dielectric material (e.g., 106), a RDL (e.g., 120) comprising a second organic dielectric material (e.g., 332) is between the first IC dies and the second interconnects, and the first interconnects have a pitch of less than 10 micrometers between adjacent interconnects.

Example 35 provides the microelectronic assembly of example 34, in which: the first organic dielectric material comprises epoxy, and the second organic dielectric material comprises polyimide.

Example 36 provides the microelectronic assembly of any one of examples 34-35, further comprising a glass panel coupled to the plurality of second IC dies, in which the second IC dies are between the glass panel and the first IC dies.

Example 37 provides the microelectronic assembly of any one of examples 34-36, in which the first interconnects comprise hybrid bonds including metal-to-metal bonds and inorganic dielectric to inorganic dielectric bonds.

Example 38 provides the microelectronic assembly of example 37, in which the metal-to-metal bonds have less than approximately 10 micrometers pitch between adjacent metal to metal bonds.

Example 39 provides the microelectronic assembly of any one of examples 37-38, in which the metal comprises copper.

Example 40 provides the microelectronic assembly of any one of examples 37-39, in which the inorganic dielectric is a compound of silicon and at least one of oxygen, nitrogen, and carbon.

Example 41 provides the microelectronic assembly of any one of examples 34-40, in which the second interconnects comprise solder.

Example 42 provides the microelectronic assembly of any one of examples 34-41, in which the RDL comprises a plurality of layers of the second organic dielectric material (e.g., 332), conductive traces (e.g., 330) and conductive vias (e.g., 331).

Example 43 provides the microelectronic assembly of example 42, in which the RDL comprises 10 layers of the second organic dielectric material.

Example 44 provides the microelectronic assembly of any one of examples 34-43, in which each of the first IC dies comprises: an interface layer comprising an inorganic dielectric material (e.g., 324) and conductive bond pads (e.g., 312); a substrate (e.g., 302) having at least one TSV (e.g., 118); and a metallization stack (e.g., 304) in contact with the substrate, the metallization stack comprising a plurality of layers of another inorganic dielectric material (e.g., 306), conductive traces (e.g., 308), and conductive vias (e.g., 310), in which: the metallization stack is between the RDL and the substrate, the substrate is between the metallization stack and the interface layer, and the first interconnects comprise the conductive bond pads of the interface layer.

Example 45 provides the microelectronic assembly of example 44, in which the TSV conductively couples the conductive traces in the metallization stack with one of the conductive bond pads of the interface layer.

Example 46 provides the microelectronic assembly of any one of examples 44-45, in which the substrate further comprises active elements (e.g., 303) proximate to the metallization stack.

Example 47 provides the microelectronic assembly of any one of examples 34-46, in which each of the second IC dies comprises: a substrate (e.g., 320); and a metallization stack (e.g., 322) in contact with the substrate, the metallization stack comprising a plurality of layers of an inorganic dielectric material (e.g., 324), conductive traces (e.g., 326), conductive vias (e.g., 328), and conductive bond pads (e.g., 316), in which: the metallization stack is between the first interconnects and the substrate, and the first interconnects comprise the conductive bond pads of the metallization stack.

Example 48 provides the microelectronic assembly of example 47, in which the substrate further comprises active elements (e.g., 321) proximate to the metallization stack.

Example 49 provides a method, comprising (e.g., FIGS. 6, 7): providing a panel comprising glass or ceramic (e.g., FIGS. 6A, 7A); providing a first IC die comprising a substrate having a first side and an opposing second side, the first IC die further comprising a metallization stack in contact with the first side of the substrate (e.g., FIGS. 6A, 7A); attaching the second side of the substrate of the first IC die to the panel (e.g., FIGS. 6A, 7A); depositing an organic dielectric material around and over the first IC die (e.g., FIGS. 6B, 7B); forming an interface layer over the metallization stack of the first IC die (e.g., FIGS. 6C, 7C); attaching a pair of second IC dies to the first IC die, the attaching comprising forming at least one conductive pathway between the pair of second IC dies through the first IC die (e.g., FIGS. 6D, 7D); depositing the organic dielectric material around the second IC dies (e.g., FIGS. 6E, 7E); and forming an RDL over the second IC dies and the organic dielectric material around the second IC dies (e.g., FIGS. 6E, 7E).

Example 50 provides the method of example 49, further comprising detaching the panel (e.g., FIGS. 6F, 7F).

Example 51 provides the method of any one of examples 49-50, further comprising coupling the RDL to a package substrate.

Example 52 provides the method of any one of examples 49-51, in which the organic dielectric material comprises epoxy material.

Example 53 provides the method of any one of examples 49-52, in which the RDL comprises polyimide material.

Example 54 provides the method of any one of examples 49-53, in which forming the interface layer comprises (e.g., FIG. 6C): forming conductive vias and conductive bond pads in the organic dielectric material over the first IC die; depositing solder resist around the conductive bond pads; and forming solder caps on the conductive bond pads.

Example 55 provides the method of any one of examples 49-54, in which attaching the second IC dies to the first IC die comprises forming solder bonds in the interface layer between the second IC dies and the first IC die.

Example 56 provides the method of any one of examples 49-55, in which forming the interface layer comprises (e.g., FIG. 7C) planarizing the organic dielectric material over the first IC die such that conductive bond pads in the metallization stack are exposed.

Example 57 provides the method of example 56, in which planarizing comprises chemical mechanical polishing (CMP).

Example 58 provides the method of any one of examples 56-57, in which attaching the second IC dies to the first IC die comprises forming hybrid bonds comprising metal-metal bonds and inorganic dielectric-inorganic dielectric bonds in the interface layer between the second IC dies and the first IC die.

Example 59 provides the method of example 58, in which: the substrate of the first IC die is a first substrate, the metallization stack of the first IC die is a first metallization stack, each of the second IC dies comprises: a layer of inorganic dielectric material with conductive bond pads therein, a second metallization stack; and a second substrate between the layer of inorganic dielectric material and the second metallization stack, and the hybrid bonds are formed between the conductive bond pads in the layer of inorganic dielectric material of the second IC dies and the conductive bond-pads in the first metallization stack of the first IC die.

Example 60 provides the method of any one of examples 49-59, further comprising: attaching a plurality of first IC dies to the panel; and attaching a plurality of pairs of second IC dies to the plurality of first IC dies, in which any one pair of the second IC dies are attached to a subset of the plurality of first IC dies.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first layer comprising a plurality of first IC dies in an organic dielectric material, the first layer having a first side and a second side opposite to the first side;
a second layer on the first side of the first layer, the second layer comprising a second IC die in the organic dielectric material, the second IC die conductively coupling a pair of first IC dies in the plurality of first IC dies of the first layer; and
a package substrate coupled to the second side of the first layer,
wherein:
the second IC die is coupled to the pair of first IC dies by interconnects having a pitch less than 60 micrometers between adjacent interconnects, and
the pair of first IC dies comprises through-substrate vias (TSVs) conductively coupling circuits in the first IC dies with the interconnects.

2. The microelectronic assembly of claim 1, wherein the organic dielectric material is an epoxy material.

3. The microelectronic assembly of claim 1, wherein:
the organic dielectric material is a first organic dielectric material,
the first layer further comprises a redistribution layer (RDL) between the plurality of first IC dies and the second side, and
the RDL comprises a plurality of layers of conductive traces and a second organic dielectric material.

4. The microelectronic assembly of claim 1, wherein:
the second layer comprises a plurality of second IC dies,
a subset of the plurality of second IC dies couples the pair of first IC dies, and
other subsets of the plurality of second IC dies couple other pairs of first IC dies in the first layer.

5. The microelectronic assembly of claim 1, wherein the interconnects comprise micro-bumps including solder caps conductively and mechanically coupled to copper pads.

6. The microelectronic assembly of claim 5, wherein the micro-bumps have approximately 25 micrometers to 60 micrometers pitch between adjacent micro-bumps.

7. The microelectronic assembly of claim 1, wherein the interconnects comprise hybrid bonds including metal-to-metal bonds and inorganic dielectric to inorganic dielectric bonds.

8. The microelectronic assembly of claim 7, wherein the metal-to-metal bonds have less than approximately 10 micrometers pitch between adjacent metal to metal bonds.

9. The microelectronic assembly of claim 1, further comprising: a panel comprising glass coupled to the second layer on a side of the second layer opposite to the first layer.

10. A microelectronic assembly, comprising:
a pair of first IC dies mutually parallel and separated by a gap;
a plurality of second IC dies coupled to the pair of first IC dies by first interconnects, the second IC dies extending across the gap, the second IC dies comprising conductive pathways between the first IC dies; and
a package substrate coupled to the pair of first IC dies by second interconnects,
wherein:
the first IC dies are between the second IC die and the package substrate,
the first IC dies and the second IC dies are surrounded by a first organic dielectric material (e.g., 106),
a RDL comprising a second organic dielectric material is between the first IC dies and the second interconnects, and
the first interconnects have a pitch of less than 10 micrometers between adjacent interconnects.

11. The microelectronic assembly of claim 10, wherein:
the first organic dielectric material comprises epoxy, and
the second organic dielectric material comprises polyimide.

12. The microelectronic assembly of claim 10, further comprising a glass panel coupled to the plurality of second IC dies, wherein the second IC dies are between the glass panel and the first IC dies.

13. The microelectronic assembly of claim 10, wherein the first interconnects comprise hybrid bonds including metal-to-metal bonds and inorganic dielectric to inorganic dielectric bonds.

14. The microelectronic assembly of claim 13, wherein the metal-to-metal bonds have less than approximately 10 micrometers pitch between adjacent metal to metal bonds.

15. The microelectronic assembly of claim 10, wherein the RDL comprises a plurality of layers of the second organic dielectric material, conductive traces and conductive vias.

16. The microelectronic assembly of claim 10, wherein each of the first IC dies comprises:
an interface layer comprising an inorganic dielectric material and conductive bond pads;
a substrate having at least one TSV; and
a metallization stack in contact with the substrate, the metallization stack comprising a plurality of layers of another inorganic dielectric material, conductive traces, and conductive vias,
wherein:
the at least one TSV conductively couples the conductive traces in the metallization stack with one of the conductive bond pads of the interface layer,
the metallization stack is between the RDL and the substrate,
the substrate is between the metallization stack and the interface layer, and
the first interconnects comprise the conductive bond pads of the interface layer.

17. A method, comprising:
providing a panel comprising glass or ceramic;
providing a first IC die comprising a substrate having a first side and an opposing second side, the first IC die further comprising a metallization stack in contact with the first side of the substrate;
attaching the second side of the substrate of the first IC die to the panel;
depositing an organic dielectric material around and over the first IC die;
forming an interface layer over the metallization stack of the first IC die;
attaching a pair of second IC dies to the first IC die, the attaching comprising forming at least one conductive pathway between the pair of second IC dies through the first IC die;
depositing the organic dielectric material around the second IC dies; and
forming an RDL over the second IC dies and the organic dielectric material around the second IC dies.

18. The method of claim 17, further comprising detaching the panel.

19. The method of claim 17, wherein attaching the second IC dies to the first IC die comprises forming solder bonds in the interface layer between the second IC dies and the first IC die.

20. The method of claim 17, wherein attaching the second IC dies to the first IC die comprises forming hybrid bonds comprising metal-metal bonds and inorganic dielectric-inorganic dielectric bonds in the interface layer between the second IC dies and the first IC die.
